(19) United States
(12) Patent Application Publication
(10) Pub. No.: US 2010/0175246 A1
(43) Pub. Date: Jul. 15, 2010

(54) COMPONENT MOUNTING SYSTEM AND COMPONENT MOUNTING METHOD

(75) Inventor: Kazuhide Nagao, Fukuoka (JP)

Correspondence Address: PEARNE & GORDON LLP, 1801 EAST 9TH STREET, SUITE 1200, CLEVELAND, OH, 44114-3108, US

(73) Assignee: PANASONIC CORPORATION, Osaka (JP)

(21) Appl. No.: 12/676,403

(22) PCT Filed: Sep. 26, 2008
(86) PCT No.: PCT/JP2008/068001

§ 371 Date: Mar. 4, 2010

(30) Foreign Application Priority Data
Sep. 27, 2007 (JP) 2007-250881

(51) Int. Cl. B23P 19/00; H05K 3/00

(52) U.S. Cl. 29/829; 29/739

(57) ABSTRACT

In a component mounting line 1 (a component mounting system) which includes substrate transport paths La, Lb, Lc which transport plural types of substrates 3 in a predetermined direction and a plurality of component mounter heads 10 which are provided along the substrate transport paths La, Lb, Lc for mounting sequentially components P on the plural types of substrates 3 which are transported by the substrate transport paths La, Lb, Lc, objects on which components are to be mounted by each movable component mounter head 10 are limited to one type of substrates 3 which are determined to be associated with that particular movable component mounter head 10.

### TECHNICAL FIELD

The present invention relates to a component mounting system and method for mounting sequentially components on substrates which are transported in a predetermined direction by a substrate transport path by a plurality of component mounter units which are provided along the substrate transport path.

### BACKGROUND ART

As a component mounting system for mounting sequentially components on substrates which are transported in a predetermined direction in a substrate transport path by a plurality of component mounter units which are provided along the substrate transport path, there has been known, for example, a component mounting line in which a plurality of component mounting apparatuses are aligned in series in a substrate transport direction and components are mounted on substrates by movable component mounter heads which are provided on the respective component mounting apparatuses while the substrates are sent and received between the adjacent component apparatuses by driving substrate transport conveyers of the respective component mounter units. In the case of this component mounting line, the continuous path in the substrate transport direction which is made up of the substrate transport conveyors of the respective component mounting apparatuses corresponds to the substrate transport path, and the movable component mounter heads provided on the respective component mounting apparatuses correspond to the component mounter units.

In a component mounting system like the one described above, in a case where a plurality of substrate transport paths are provided in a direction which is orthogonal to the substrate transport direction, since components can be mounted on a plurality of substrates at one time, the production rate of substrates can be increased (JP-A-2004-31613 and JP-A-2004-265887).

In addition, in a component mounting system like the one described above, in the event that plural types of substrates are made to be transported in series on the substrate transport path and the respective component mounter units are made to execute selectively component mounting operations corresponding to the types of substrates so transported, components can be mounted on the plural types of substrates.

However, as has been described above, in the event that the configuration is adopted in which plural types of substrates are made to be transported in series on the substrate transport path and the respective component mounter units are made to execute selectively component mounting operations corresponding to the types of substrates so transported, there has been caused a problem that mounting errors tend to occur more easily and hence, the production rate of non-defective products is decreased to a lower level than a case where only one type of substrate is transported on the substrate transport path and the respective component mounter units are made to execute only one type of component mounting operation at all times (a case in which the whole component mounting line is made to perform a component mounting operation on one type of substrate).

### DISCLOSURE OF THE INVENTION

Then, the invention has been made in view of the situations and an object thereof is to provide a component mounting system and a component mounting method in which mounting errors of mounting components on plural types of substrates are made difficult to occur, so as to increase the production rate of non-defective products, compared with the related art system and method.

According to a first aspect of the invention, there is provided a component mounting system comprising:

at least one substrate transport path for transporting plural types of substrates in a predetermined direction; and

a plurality of component mounter units which are provided along the substrate transport path for mounting sequentially components on the plural types of substrates which are transported in the substrate transport path,

wherein an object to which each component mounter unit mounts components is limited to only one type of the substrates determined corresponding to each component mounter unit.

According to a second aspect of the invention, there is provided a component mounting system as set forth in the first aspect of the invention, wherein a plurality of the substrate transport paths are arranged in parallel along a direction which is orthogonal to the predetermined direction of the substrate transport path and the substrates are transported separately in the substrate transport paths corresponding to the types of the substrates.

According to a third aspect of the invention, there is provided a component mounting method for mounting sequentially components on plural types of substrates which are transported in a predetermined direction in at least one substrate transport path by a plurality of component mounter units which are provided along the substrate transport path, wherein an object to which each component mounter unit mounts components is limited to only one type of the substrates determined corresponding to each component mounter unit.

According to a fourth aspect of the invention, there is provided a component mounting method as set forth in the third aspect of the invention, wherein the substrates are transported separately in a plurality of the substrate transport paths corresponding to the types of the substrates which are arranged in parallel along a direction which is orthogonal to the predetermined direction of the substrate transport path.

According to the aspects of the invention, since the object on which components are mounted by each component mounter unit is limited to the one type of substrate which is determined to be associated with the particular component mounter unit and each component mounter unit is made only to mount components on the one type of substrate which is associated therewith, even in the event that plural types of substrates are transported on the substrate transport path so that components are mounted on the plural types of substrates so transported, the respective component mounter units perform only one type of component mounting operation, and therefore, mounting errors are made difficult to occur, thereby making it possible to increase the production rate of non-defective products as compared with the conventional component mounting systems and methods.

### BRIEF DESCRIPTION OF THE DRAWINGS

FIG. 1 is a plan view of a component mounting line according to an embodiment of the invention.

FIG. 2 is a plan view of a component mounting apparatus according to the embodiment of the invention.

FIG. 3 is a partial side view of the component mounting apparatus according to the embodiment of the invention.

FIG. 4 is a block diagram showing a control system of the component mounting apparatus according to the embodiment of the invention.

### BEST MODE FOR CARRYING OUT THE INVENTION

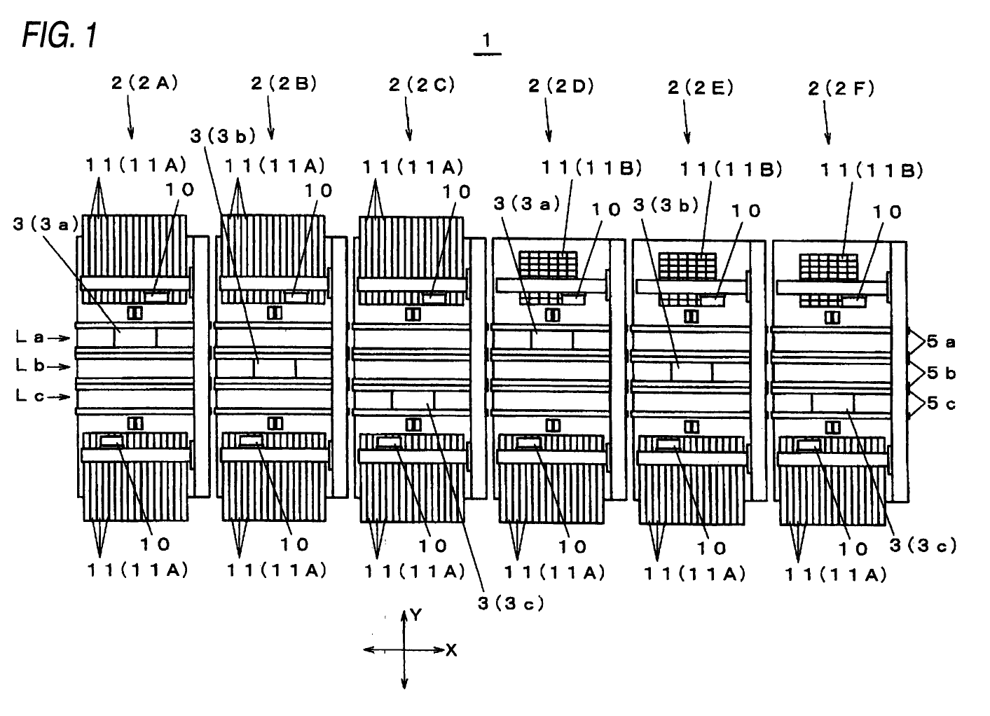

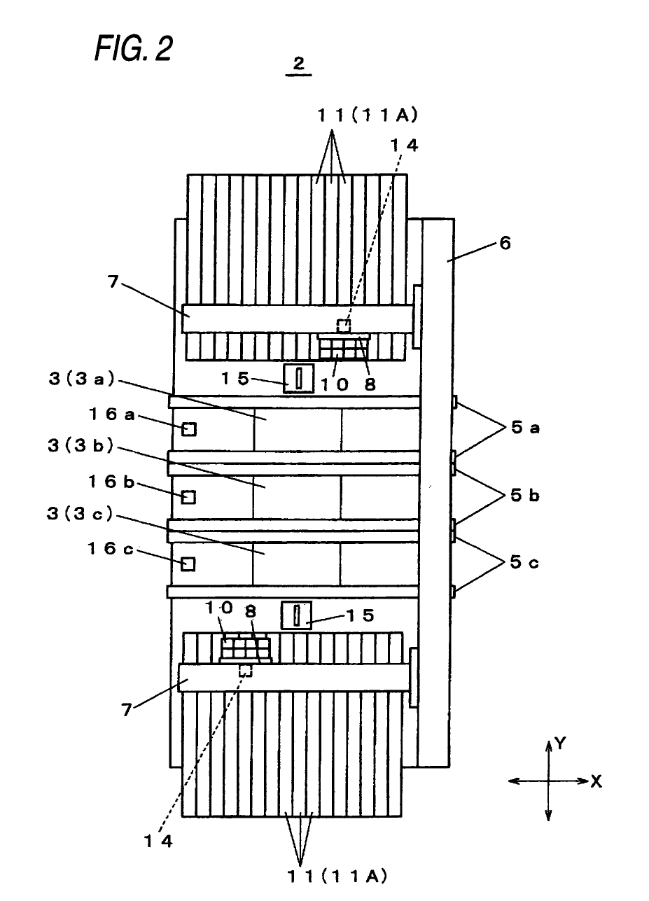

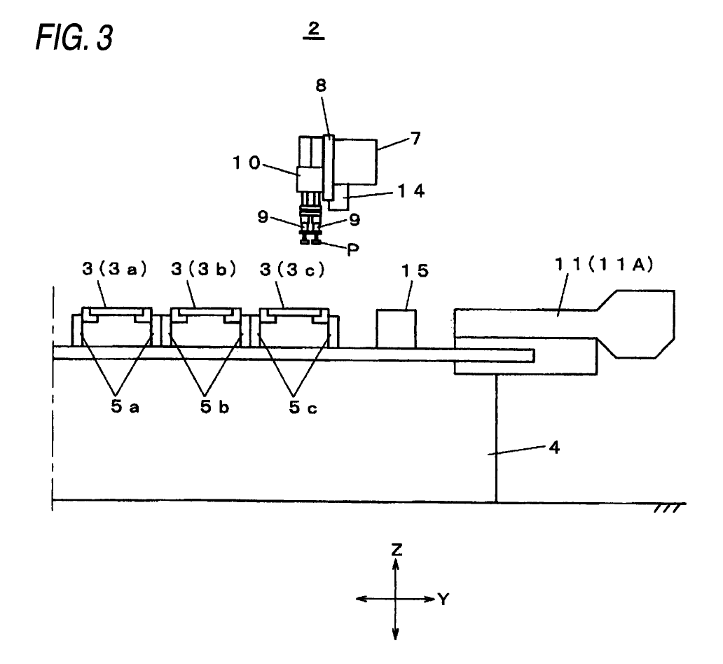

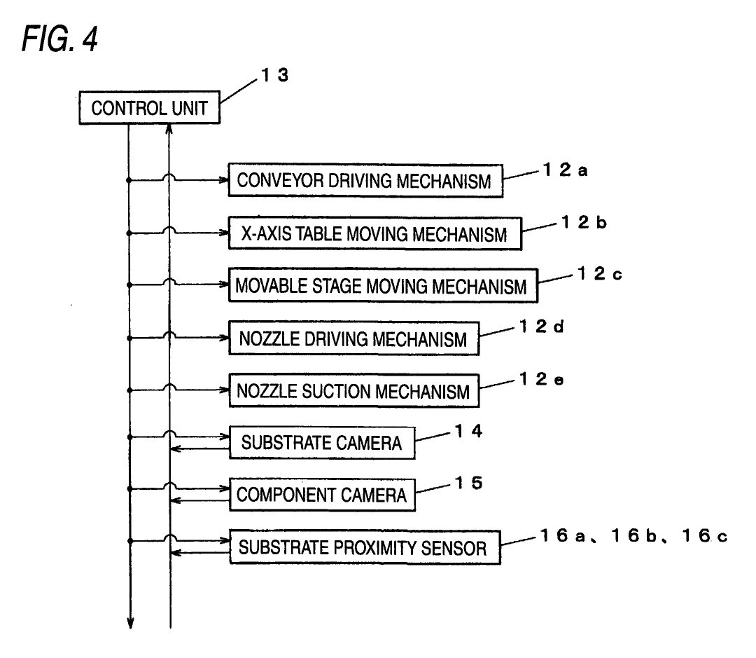

Hereinafter, an embodiment of the invention will be described by reference to the drawings. FIG. 1 is a plan view of a component mounting line according to an embodiment of the invention, FIG. 2 is a plan view of a component mounting apparatus according to the embodiment of the invention, FIG. 3 is a partial side view of the component mounting apparatus according to the embodiment of the invention, and FIG. 4 is a block diagram showing a control system of the component mounting apparatus according to the embodiment of the invention.

In FIG. 1, a component mounting line 1 illustrates one embodiment of a component mounting system of the invention, which is configured such that a plurality of component mounting apparatuses 2 are aligned in series in a direction in which substrates 3 are transported (an X-axis direction). In FIG. 1, although only six component mounting apparatuses 2 are depicted, it should be understood that another plurality of component mounting apparatuses 2 are aligned in the X-axis direction in addition to the six component mounting apparatuses 2.

In FIGS. 2 and 3, three substrate transport conveyors 5a, 5b, 5c are provided on a base 4 of each component mounting apparatus 2 so as to be disposed parallel to one another while each extending in the X-axis direction, and a Y-axis table 6 is provided above these three substrate transport conveyors 5a, 5b, 5c so as to extend in a horizontal direction (a Y-axis direction) which intersects the X-axis direction at right angles. Two X-axis tables 7 are provided on the Y-axis table 6 such that the X-axis tables 7 not only extend in the X-axis direction while being supported on the Y-axis table 6 at one ends thereof but also move freely along the Y-axis table 6. A movable stage 8 is provided on each X-axis table 7 so as to freely move in the X-axis direction along the X-axis table 7, and a movable component mounter head (component mounter unit) 10 including a plurality of downwardly extending suction nozzles 9 is attached to each movable stage 8.

In FIG. 1, the three substrate transport conveyors 5a, 5b, 5c provided on each component mounting apparatus 2 are made to be continued from, at their upstream ends (left ends in FIG. 1), and continue to, at their downstream ends (right ends in FIG. 1), three substrate transport conveyors 5a, 5b, 5c provided on the other adjacent component mounting apparatuses 2 so as to make up three components transport paths La, Lb, Lc (FIG. 1), and the substrate transport paths so constituted are each made to transport substrates 3 in a predetermined direction (the X-axis direction).

In FIGS. 1 and 2, parts feeders 11 for feeding or supplying components P (FIG. 3) to their associated movable component mounter heads 10 are provided in positions which lie so as to hold the three substrate transport conveyors 5a, 5b, 5c on the base 4 of the component mounting apparatus 2 from both sides in the Y-axis direction. There are some types of parts feeders, and a tape feeder 11A and a tray feeder 11B are available as the parts feeder 11.

In FIG. 4, provided on each component mounting apparatus 2 are conveyor driving mechanisms 12a for driving individually the three substrate transport conveyors 5a, 5b, 5c, X-axis table moving mechanisms 12b for moving individually the X-axis tables 7 along the Y-axis table 6, movable stage moving mechanisms 12c for moving individually the movable stages 8 along the X-axis tables 7, nozzle driving mechanisms 12d for lifting up and down and rotating about a vertical axis (a Z-axis) individually the suction nozzles 9 and nozzle suction mechanisms 12e for actuating individually the suction nozzles 9 for sucking operation. The operations of the conveyor driving mechanisms 12a, the X-axis table moving mechanisms 12b, the movable stage moving mechanisms 12c, the nozzle driving mechanisms 12d and the nozzle suction mechanisms 12e are controlled by a control unit 13 provided on the component mounting apparatus 2, whereby transportation and positioning of substrates 3 by the three substrate transport conveyors 5a, 5b, 5c, movement of the two movable component mounter heads 10 and suction of components P by the two movable component mounter heads 10 are implemented.

In FIGS. 2 and 3, a substrate camera 14, whose photographing or image sensing surface is oriented downwards, is provided on the movable stage 8 of each component mounting apparatus 2, and component cameras 15, whose photographing or image sensing surfaces are oriented upwards, are provided on the base 4. The operations of the substrate cameras 14 and the component cameras 15 are controlled by the control unit 13 (FIG. 4).

In FIG. 2, substrate proximity sensors 16a, 16b, 16c are provided on the base 4 in positions which correspond, respectively, to upstream-end portions of the three substrate transport conveyors 5a, 5b, 5c provided on each component mounting apparatus 2. When substrates 3 transferred from the substrate transport conveyors 5a, 5b, 5c of the other component mounting apparatus lying upstream approach closely the three substrate proximity sensors 16a, 16b, 16c, the substrate proximity sensors 16a, 16b, 16c detect the approaching substrates 3 and output a substrate approaching signal to the control unit 13 (FIG. 4).

When receiving a substrate approaching signal that is outputted from any of the three substrate proximity sensors 16a, 16b, 16c, the control unit 13 of each component mounting apparatus 2 actuates one of the substrate transport conveyors 5a, 5b, 5c which is associated with the one of the substrate proximity sensors 16a, 16b, 16c which outputs the substrate approaching signal, so that the substrate 3 that has been transported from the other component mounting apparatus 2 lying upstream is transferred to the specific one of the substrate transport conveyors 5a, 5b, 5b for further transportation so as to locate the substrate 3 in a predetermined position where components P are mounted thereon. Then, the X-axis table moving mechanism 12b and the movable stage moving mechanism 12c are actuated to move the movable component mounter head 10, and the substrate camera 14 which has now been moved to a position above the substrate is made to image recognize a registration mark (not shown) provided in a corner of the substrate 3. Image information on the registration mark image recognized by the substrate camera 14 is sent to the control unit 13 (FIG. 4), and the control unit 13 then determines how far the registration mark is offset from a predetermined reference position based on the image information sent from the substrate camera 14 for detection of a position error of the substrate 3.

When detecting a position error of the substrate 3, the control unit 13 causes the movable component mounter head 10 to move to a position above the parts feeder 11 and causes the suction nozzles 9 to pick up components P supplied by the parts feeder 11 by vacuum. Then, the control unit 13 controls the movable component mounter head 10 such that the components P picked up by vacuum with the suction nozzles 9 pass over (within the field of vision of the component camera 15) the component camera 15 and causes the component camera 15 to image recognize (image sense) lower surfaces of the components P. Image information on the lower surfaces of the components P that is obtained through image recognition by the component camera 15 is sent to the control unit (FIG. 4), and the control unit 13 determines how far the components P are offset from proper positions on the suction nozzles 9 based on the image information set from the component camera 15 for detection of position errors (suction errors) of the components P relative to the suction nozzles 9.

When detecting the position error of the substrate 3 and the suction errors of the components P in the ways described above, the control unit 13 of each component mounting apparatus 2 mounts the components P held by vacuum with the suction nozzles 9 on the substrate 3 based on mounting position data given to the components P. As this occurs, the control unit 13 corrects the mounting position data such that the position error of the substrate 3 and the position errors of the components P are modified properly and then mount the components P in correct positions on the substrate 3. In this way, the movable component mounter heads 10 provided on each component mounting apparatus 2 make up a plurality of component mounter units for mounting sequentially components on substrates 3 which are transported by the substrate transport paths La, Lb, Lc in the component mounting line 1.

When the components P have been mounted on the substrate 3, the control unit 13 actuates the one of the substrate transport conveyors 5a, 5b, 5c on which the substrate 3 is mounted to send the substrate 3 down to the component mounting apparatus 2 lying downstream.

Thus, the component mounting line 1 is configured such that while driving the three substrate transport conveyors 5a, 5b, 5c of each component mounting apparatus 2 to receive and transfer substrates 3 from and to the adjacent upstream and downstream component mounting apparatuses 2, components P are mounted on the substrates 3 by the two movable component mounter units 10. In addition, finally, a substrate on which components are completely mounted is put out from the component mounting apparatus 2 installed in a downstreammost position in the component mounting line 1.

Here, in the component mounting line 1 according to the embodiment, in the event that substrates 3 of the same type are made to be transported by the three substrate transport paths La, Lb, Lc for mounting components on the substrates 3 of the single type, the control unit 13 provided on each component mounting apparatus 2 causes the two movable component mounter heads 10 provided on the component mounting apparatus 2 to mount components P on all substrates 3 which are transported by the three substrate transport paths La, Lb, Lc (the substrate transport conveyors 5a, 5b, 5c).

On the other hand, in the event that substrates 3 of plural types (here, three types) are made to be transported by the three substrate transport paths La, Lb, Lc for mounting components on the substrates 3 of the plural types (in FIG. 1, denoted, respectively, by reference numerals 3a, 3b, 3c), the control unit 13 provided on each component mounting apparatus 2 causes the movable component mounter heads 10 provided on the component mounting apparatus 2 to mount components P on the substrates 3 of one type of the substrates 3 (3a, 3b, 3c) of the three types which are transported altogether by the three substrate transport paths La, Lb, Lc (the substrate transport conveyors 5a, 5b, 5c), the substrates 3 of the one type determined corresponding to the movable component mounter heads 10 of the particular component mounting apparatus 2, rather than causing the movable component mounter heads 10 to selectively mount components P on the substrates 3 of the three types so transported in accordance with the types thereof. Namely, in this component mounting line 1, an object to which each movable component mounter head 10 mounts the components P is limited to substrates 3 of only one type which is determined corresponding to the particular component mounter head 10, and each component mounter head 10 is made to mount components P only on substrates of the one type associated therewith.

For example, assuming that the six component mounting apparatuses 2 shown in FIG. 1 are denoted by 2A, 2B, 2C, 2D, 2E, 2F in that order from the upstream side, the two movable component mounter heads 10 provided on the component mounting apparatus 2A and the component mounting apparatus 2D are made to mount components P only on substrates 3a which are transported by the substrate transport path La, the two movable component mounter heads 10 provided on the component mounting apparatus 2B and the component mounting apparatus 2E are made to mount components P only on substrates 3a which are transported by the substrate transport path Lb, and the two movable component mounter heads 10 provided on the component mounting apparatus 2C and the component mounting apparatus 2F are made to mount components P only on substrates 3a which are transported by the substrate transport path Lc. In addition, substrates 3 on which no component P is mounted in each component mounting apparatus 2 are simply transported from the upstream end to the downstream end by the substrate transport conveyors 5a, 5b, 5c (the substrates 3 are only passed through the particular component mounting apparatus 2.

The relationship between each movable component mounter head 10 on each component mounting apparatus 2 and the type of substrates 3 associated therewith is stored in a storage, not shown, of the control unit 13 provided on the particular component mounting apparatus 2, and although the control unit 13 can refer to the associated relationship at all times, the associated relationship is made to be changed arbitrarily by the operator.

The component mounting line 1 (the component mounting system) of the embodiment of the invention is configured so as to include the substrate transport paths La, Lb, Lc which transport the plural types of substrates 3 in the predetermined direction (the X-axis direction) and the plurality of movable component mounter heads 10 (the component mounter units) which mount sequentially components P on the plural types of substrates 3 which are transported by the substrate transport paths La, Lb, Lc, and the object to which each movable component mounter head 10 mounts the components P is limited to the one type of substrates 3 which are determined corresponding to the particular movable component mounter head 10.

In addition, according to the embodiment of the invention, there is provided a component mounting method for mounting sequentially components P on plural types of substrates 3 which are transported in a predetermined direction by substrate transport paths La, Lb, Lc by a plurality of movable component mounter heads 10 which are provided along the substrate transport paths La, Lb, Lc, wherein an object to which each movable component mounter head 10 mounts components P is limited to one type of substrates which are determined corresponding to that particular movable component mounter head 10.

Thus, in the component mounting line 1 (the component mounting system) and the component mounting method according to the embodiment of the invention, since the object to which each movable component mounter head 10 (the component mounter unit) mounts components is limited to only one type of substrates 3 which are determined corresponding to that particular component mounter head 10 and each movable component mounter head 10 is made to mount components P only on the one type of substrates 3 so associated therewith, even in the event that plural types of substrates 3 are made to be transported by the substrate transport paths La, Lb, Lc for mounting components P on the plural types of substrates 3, since each movable component mounter head 10 is made to perform only one type of component mounting operation, mounting errors are made difficult to occur, thereby making it possible to increase the production rate of good product, compared to the conventional component mounting systems and methods.

In addition, in the component mounting line 1 according to the embodiment of the invention, the plurality of (three) substrate transport paths are provided in parallel in the direction (the Y-axis direction) which intersects the direction in which substrates 3 are transported (the X-axis direction) at right angles, and the plural (three) types of substrates 3 are transported separately by the plurality of substrate transport paths La, Lb, Lc corresponding to the types of the substrates. Because of this, by ensuring the association of the respective movable component mounter heads 10 with the substrate transport conveyors 5a, 5b, 5c which transport substrates 3 which constitute objects on which components P are to be mounted by the movable component mounter heads 10, the transportation of substrates 3 which constitute objects on which components P are to be mounted can be detected only by the transportation of substrates 3 from the associated substrate transport conveyors 5a, 5b, 5c without identifying the types of substrates 3 transferred from the component mounting apparatus 2 lying upstream.

While the embodiment of the invention has been described heretofore, the invention is not limited to the embodiment so described. For example, while in the embodiment, the two movable component mounter heads 10 provided on each component mounting apparatus 2 are such as to mount components P on the same type of objects (the same type of substrates 3), as has been described above, an object to which each movable component mounter head 10 mounts components P only have to be limited to only one type of substrates 3 corresponding to that particular movable component mounter head 10, and hence, the two movable component mounter heads 10 provided on each component mounting apparatus 2 may be such as to mount components P individually on different types of objects (different types of substrates 3).

In addition, while in the embodiment, each component mounting apparatus 2 includes the three substrate transport paths La, Lb, Lc and these three substrate transport paths La, Lb, Lc are made to transport separately the plural types of substrates 3 in accordance with the type, the number of substrate transport paths does not have to be limited to three, and hence, four substrate transport paths may be provided. In addition, while in the embodiment, each component mounting apparatus 2 includes the two movable component mounter heads 10, this is only an example, and hence, each component mounting apparatus 2 may include any number of movable component mounter heads 10.

In addition, while the component mounting system (the component mounting line 1) that has been described above is such as to have the plurality of substrate transport paths, even in the case where the component mounting system has only one substrate transport path, in the event that a configuration is adopted in which plural types of substrates are made to be transported in series on the single substrate transport path for mounting sequentially components on the plural types of substrates so transported by a plurality of movable component mounter heads which are provided along the substrate transport path, components can be mounted on the plural types of substrates. In addition, in the event that an object to which each movable component mounter head mounts components is limited to only one type of substrates which are determined corresponding to that particular movable component mounter head, the same advantage obtained by the aforesaid embodiment can be obtained. In this case, however, the types of substrates transported by the substrate transport conveyor needs to be identified at each component mounting apparatus. As a method for identifying the type of substrate that has been so transported to each component mounting apparatus, for example, a method can be considered in which a number of small holes specific to a type of substrate are provided in the same type of substrates in the direction in which the substrates are transported, and a photo sensor is disposed on the base in a position corresponding to the upstream end of the substrate transport conveyor for detecting the number of small holes in a substrate which passes thereby to identify the type of the substrate.

The invention provides a component mounting system and a component mounting method which can make it difficult for mounting errors to be produced when mounting components on plural types of substrates, so as to increase the production rate of non-defective products, compared with conventional component mounting systems and methods.

1. A component mounting system comprising:
at least one substrate transport path for transporting plural types of substrates in a predetermined direction; and
a plurality of component mounter units which are provided along the substrate transport path for mounting sequentially components on the plural types of substrates which are transported in the substrate transport path,
wherein an object to which each component mounter unit mounts components is limited to only one type of the substrates determined corresponding to each component mounter unit.

2. A component mounting system as set forth in claim 1, wherein a plurality of the substrate transport paths are arranged in parallel along a direction which is orthogonal to the predetermined direction of the substrate transport path and the substrates are transported separately in the substrate transport paths corresponding to the types of the substrates.

3. A component mounting method for mounting sequentially components on plural types of substrates which are transported in a predetermined direction in at least one substrate transport path by a plurality of component mounter units which are provided along the substrate transport path, wherein an object to which each component mounter unit mounts components is limited to only one type of the substrates determined corresponding to each component mounter unit.

4. A component mounting method as set forth in claim 3, wherein the substrates are transported separately in a plurality of the substrate transport paths corresponding to the types of the substrates which are arranged in parallel along a direction which is orthogonal to the predetermined direction of the substrate transport path.
